(19) United States
(12) Patent Application Publication
(10) Pub. No.: US 2007/0274050 A1
(43) Pub. Date: Nov. 29, 2007

(54) Composite anti-disturbed flow heat sink

(76) Inventor: Han-Ming Lee, Hsin Chu City (TW)

Correspondence Address: Han-Ming Lee, P.O. BOX 7-820, TAIPEI, omitted

(21) Appl. No.: 11/440,860

(22) Filed: May 26, 2006

(51) Int. Cl. H05K 7/20

(52) U.S. Cl. 361/710

(57) ABSTRACT

The protruding tail of the fin on the upper side of the heat sink is formed as a cone, hence the blowing-in airflow follows the lead to the bottom resulting in better performance of ejection.

There is a tooling hole on the side plate of the underside in the heat sink for the convenience of separating the adjacency heat sinks and separators in suitable space.

There is also a corresponding retaining hole above the separator. This will force the two rivets pass through the fixed body in order. The thin cone heat sink could increase the space of the separators and double the area of the heat radiation, help the airflow absorb the heat following the surrounding air and simultaneously increase the heat ejection performance so as to achieve the main usages for the industry of cooling down the chip rapidly.

### BACKGROUND OF THE INVENTION

(A) Field of the Invention

This invention proposes a composite anti-disturbed flow heat sink, which is composed of multiple heat sinks, separators and two rivets. Its main features are described as the following.

(B) Description of the Prior Art

By observation, most components for heat sinking inside the electrical products (LED display panel) utilize an aluminum press thermoform heat sinks for absorbing the heat. Shown as FIG. 5. This will generate some disturbed flow to the direction of the blowing-in air on the upper side of the aluminum material. Accordingly, the cool air fails to reach the bottom of the heat sink swimmingly and the circumstance of gathering heat on the bottom will come into existence. Furthermore, there are high thicknesses for these aluminum materials, the cool airflow could only discharge some heat on the surface of the upper side; most heat is still stay inside the aluminum materials. Thus the performance of heat sinking is poor. It's unable to address the need of high-speed for current CPU/Chip heat sinking and cooling. This is indeed a great bottleneck to be removed in the cooling industry.

### SUMMARY OF THE INVENTION

The primary objective of the present invention is to provide a composite anti-disturbed flow heat sink, especially indicating the one which is composed of multiple heat sinks, separators and two rivets and features on using the thin separator to increase the space of heat sinking surface.

The secondary objective of the present invention is to provide a composite anti-disturbed flow heat sink, whose protruding tail of the upper side of the heat sink is formed as a cone that helps the blowing-in airflow follow the lead to the bottom to get better performance of ejection.

Another objective of the present invention is to provide a composite anti-disturbed flow heat sink with a tooling hole on the side plate of the underside for the convenience of separating the adjacency heat sinks and separators in arbitrary space to facilitate the performance.

### BRIEF DESCRIPTION OF THE DRAWINGS

FIG. 1 is the illustration of preferred embodiment for this invention;

FIG. 2 The decomposition diagram of the components of this invention;

FIG. 3 The constitution diagram of the components of this invention;

FIG. 4 Another example applying this case;

FIG. 5 is the illustration of the circumstance of the heat gathering and disturbed flow in the past aluminum press thermoform.

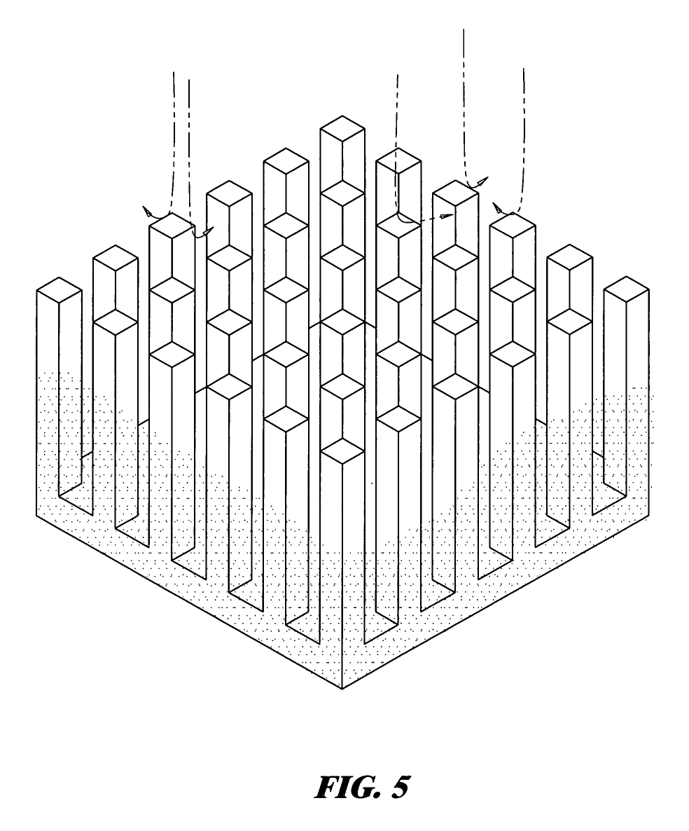

### DETAILED DESCRIPTION OF THE PREFERRED EMBODIMENT

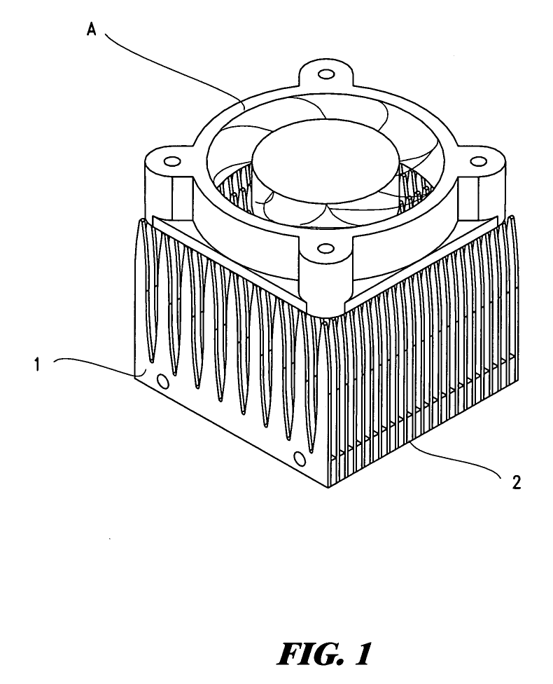

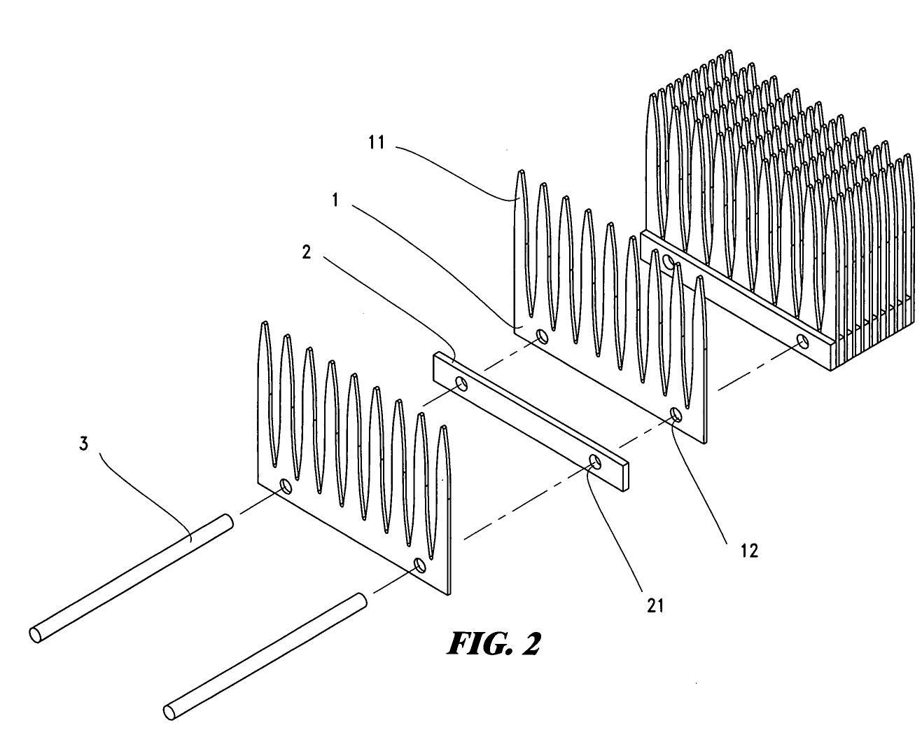

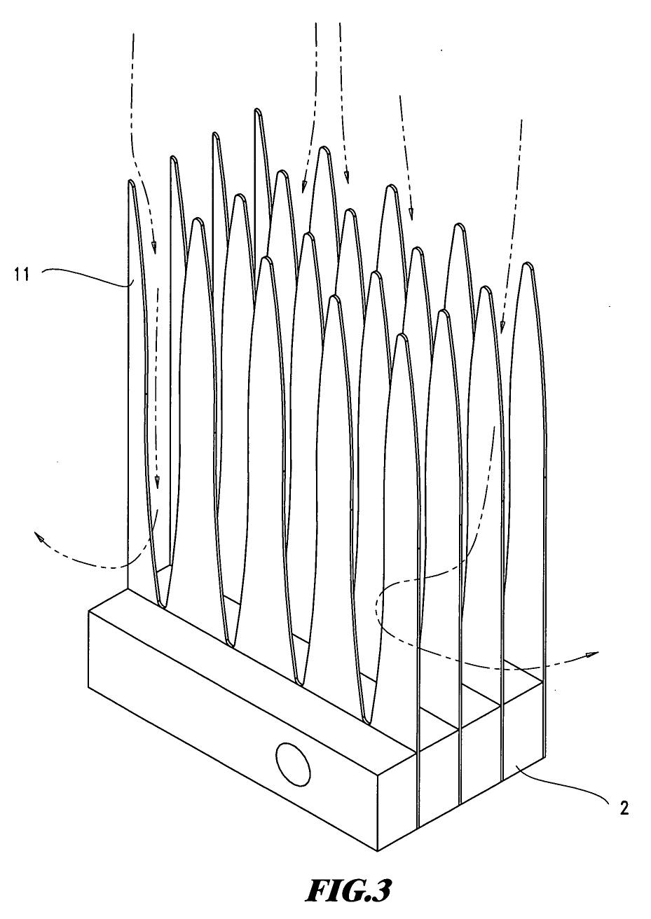

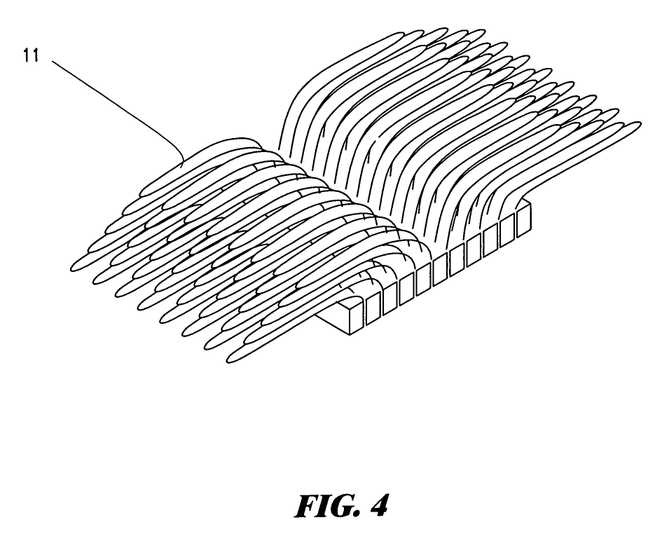

Please refer to FIGS. 1 to 4. The invention is a composite anti-disturbed flow heat sink comprised of multiple heat sinks (1), separators (2) and two rivets (3). Heat sinks (1) are made by a thin superconducting material. There are several fins (11) protruding separately on the upper side of the heat sink. And they are formed as the cone shape. There is a tooling hole (12) on the side plate of the underside on the heat sink. Separators (2) are the boards on the bottom of the corresponding heat sinks (1) and made by superconducting material as well. There is also a retaining hole (21) corresponding to the tooling hole (12) on the side of the boards for every separator spaced at intervals to generate space. This will force the two rivets (3) pass through the fixed body in order as the main featured structure of this case.

In the application of the general chips, this invention can be stuck on the surfaces of the chips directly. By means of the space distribution of the heat sinks composed of superconducting and high heat sinking materials, the surrounding air could absorb the heat rapidly and reach the performance of chip cooling. While applying to the high-heat-energy components, such as CPU, the fan (A) above the heat sinks can deliver the airflow following the tail of the coin fins (11) to the bottom and absorb the heat for the performance of ejection. The surrounding air absorbs the heat rapidly to reach the goal of cooling effect and thereby enhance the value of the case in the industry significantly.

While the present invention has been described in connection with what is considered the most practical and preferred embodiment, it is understood that the invention is not limited to the disclosed embodiments but is intended to cover various arrangements included within the spirit and scope of the broadest interpretation and equivalent arrangements.

What is claimed is:

1. A composite anti-disturbed flow heat sink composed of multiple heat sinks, separators and at least two rivets. There are separating protruding fins on the upper side of the heat sink and are formed as a cone in the tail. There is a tooling hole on the side plate of the underside on the heat sink. Separators are the boards on the bottom of the corresponding heat sinks. There are also retaining holes on the side of these boards for every separator spaced at intervals to generate space. This will force the rivets pass through the fixed body in order. Lean on the cone tail of the fins above the heat sinks, the airflow leads the surrounding air to the bottom to absorb and discharge heat to reach the featured goal of cooling the chips rapidly.
